(19) United States
(12) Patent Application Publication
(10) Pub. No.: US 2011/0146779 A1
(43) Pub. Date: Jun. 23, 2011

(54) Sub-wavelength structure layer, method for fabricating the same and photoelectric conversion device applying the same

(75) Inventors: Edward Yi Chang, Baoshan Township (TW); Kartika Chandra Sahoo, Govindpur (IN); Men-Ku Lin, Taipei City (TW); Yi-Yao Lu, Taipei City (TW); Sheng-Ping Wang, Jhubei City (TW)

(73) Assignee: National Chiao Tung University, Hsinchu (TW)

(21) Appl. No.: 12/659,955

(22) Filed: Mar. 26, 2010

(30) Foreign Application Priority Data
Dec. 22, 2009 (TW) 098144206

(51) Int. Cl. H01L 31/0224; H01L 31/18; H01L 31/0352

(52) U.S. Cl. 136/256; 438/63; 257/184; 257/431; 257/E31.032; 257/E31.126

(57) ABSTRACT

The present invention relates to a method for fabricating a sub-wavelength structure layer, including: forming a metal film on a passivation layer, an n-GaN layer or a transparent conductive oxide layer; performing thermal treatment to form self assembled metal nano particles; using the metal nano particles as a mask to remove a partial area of the passivation layer, the n-GaN layer or the transparent conductive oxide layer to form a sub-wavelength structure of which the cross-sectional area increases along the thickness direction of the passivation layer, the n-GaN layer or the transparent conductive oxide layer; and removing the metal nano particles. In addition, the present invention further provides the obtained sub-wavelength structure layer and a photoelectric conversion device using the same.

### BACKGROUND OF THE INVENTION

1. Field of the Invention

The present invention relates to a sub-wavelength structure layer and its manufacturing method and application and, more particularly, to a sub-wavelength structure layer suitable for a photoelectric conversion device and its manufacturing method and application.

2. Description of Related Art

Antireflective layers can be applied in various products, and more particularly, in the solar energy industry that has developed rapidly in recent years. The solar cell is a photoelectric conversion device to convert light into electricity. The most common known solar cell is configured as a p-n junction, which is formed by joining p-type and n-type semiconductors together in very close contact. After the p-n junction absorbs light and separates electrons and holes, the electric field opposes the obtained electrons and holes moving to the n-type and p-type semiconductors respectively to contribute current. Finally, the current is derived out through electrodes to form electricity for usage or storage. The above-mentioned phenomenon is called photovoltaic effect. Incident light is the energy source of a solar cell, and thereby the amount of light extraction is closely associated with the efficiency of a solar cell. Accordingly, in order to efficiently enhance the amount of light extraction, the application of the antireflective layer in a solar cell is important.

FIG. 1A shows a basic structure of a conventional solar cell. As shown in FIG. 1A, the conventional solar cell mainly includes: a p-type semiconductor layer 11; an n-type semiconductor layer 12, disposed on the p-type semiconductor layer 11; a first electrode 13, connected to the p-type semiconductor layer 11; and a second electrode 14, connected to the n-type semiconductor layer 12. Herein, the second electrode 14 provided at the light incident surface has an open area A and is in an interdigitated form to increase the light incident area. In addition, in order to increase the amount of light extraction, an antireflective layer 15 is disposed in the open area A of the second electrode 14 to reduce the reflection of the incident light. Traditionally, an antireflective layer is formed by coating and may have a single-layer or multi-layer structure. Although the use of the antireflective layer with a multi-layer structure can efficiently reduce the reflection of the incident light, the manufacturing cost therefore is higher and its application is restricted due to thermal mismatch and thermal diffusion. Thereby, solar cells mainly use an antireflective film with a single-layer structure.

Additionally, an antireflective layer with a textured surface (i.e. an antireflective layer with a sub-wavelength antireflective structure) was suggested. In comparison to an antireflective layer fabricated by coating, an antireflective layer with a sub-wavelength antireflective structure exhibits an antireflection effect over a broad range of the solar spectrum, and has high development potential with no restriction on material selection. FIG. 1B shows a schematic view of a conventional solar cell where an antireflective layer with a sub-wavelength antireflective structure is applied. As shown in FIG. 1B, the basic structure of the solar cell is the same as that shown in FIG. 1A, except that the antireflective layer 15 applied in the solar cell has a submicro-textured surface (i.e. a sub-wavelength antireflective structure 151). Mainly, the sub-wavelength antireflective structure is fabricated by an expensive and complex photolithography process.

FIG. 1C shows a cross-sectional view of another conventional solar cell (i.e. a thin-film solar cell). As shown in FIG. 1C, the conventional solar cell includes: an n-type semiconductor layer 171; an intrinsic layer 172, disposed on the n-type semiconductor layer 171; a p-type semiconductor layer 173, disposed on the intrinsic layer 172; a first electrode 13, connected to the n-type semiconductor layer 171; a second electrode 14 made of a transparent conductive oxide (e.g. ITO or AZO), connected to the p-type semiconductor layer 173; and a transparent substrate 16, disposed on the second electrode 14. Herein, in order to improve light absorption by enhancing light trapping, the second electrode 14 is textured by an expensive and complex lithography process to form a textured surface 141, and the subsequent thin films deposited thereover generally follow the topography of the surface below it.

In addition to solar cells, surface texture is also an important issue for LEDs (light-emitting diodes). Regarding LEDs, surface texturization can reduce total reflection and thus enhance light output.

FIG. 1D shows a cross-sectional view of a conventional GaN-based LED. As shown in FIG. 1D, the conventional GaN-based LED mainly includes: a nucleation layer 18; an n-GaN layer 191, disposed on the nucleation layer 18; an active layer 192, disposed on the n-GaN layer 191; a p-GaN layer 193 with a textured surface 19a, disposed on the active layer 192; a first electrode 13, connected to the n-GaN layer 191; and a second electrode 14, connected to the p-GaN layer 193. Herein, the textured surface 19a of the p-GaN layer 193 can reduce total reflection, thus enhancing the light output of the GaN-based LED. In general, texturization on the surface of the p-GaN layer 193 is performed by dry or wet etching, where an expensive and complex lithography process is required to define the pattern in dry etching.

### SUMMARY OF THE INVENTION

The object of the present invention is to provide a method for fabricating a sub-wavelength structure layer, where a sub-wavelength structure is fabricated by a simple and low cost technology to obtain an antireflective layer with an excellent antireflection effect. Also, the inventors provide an idea that the above-mentioned method for fabricating a sub-wavelength structure can be applied to texturing the surface of an n-GaN layer for thin GaN flip chip LED process to enhance the light output power and for vertical LED (thin GaN) process, and can be applied to texturing the surface of an transparent conductive oxide layer (TCO layer) to enhance light trapping of a thin-film solar cell or the like.

To achieve the object, the present invention provides a method for fabricating a sub-wavelength structure layer, including: forming a metal film on a passivation layer, an n-GaN layer or a transparent conductive oxide layer; performing thermal treatment on the metal film to form self assembled metal nano particles; using the metal nano particles as a mask to remove a partial area of the passivation layer, the n-GaN layer or the transparent conductive oxide layer to form a sub-wavelength structure, where the cross-sectional area of the sub-wavelength structure increases along the thickness direction of the passivation layer, the n-GaN layer or transparent conductive oxide layer; and removing the metal nano particles. Specifically, the passivation layer of the present invention may be made of silicon nitride or silicon oxide, and the transparent conductive oxide layer may be made of tin oxide, indium tin oxide, zinc oxide, aluminum-doped zinc oxide, gallium-doped zinc oxide or indium zinc oxide.

Accordingly, in the present invention, a sub-wavelength structure is fabricated through self-assembly of metal upon being heated. In comparison to a conventional photolithography process, the present invention has advantages in low cost and simple process. Additionally, the passivation layer with the sub-wavelength structure on a surface thereof according to the present invention can be used as an antireflection layer and exhibits a better antireflection effect than a film-shaped antireflective layer fabricated by a conventional coating process. Besides, the n-GaN layer with the sub-wavelength structure on a surface thereof can enhance light output in the case of being applied in an LED device or the like, while the transparent conductive oxide layer with the sub-wavelength structure on a surface thereof can enhance light trapping and thus improve light absorption in the case of being applied in a thin-film solar cell or the like. Moreover, in comparison to a conventional process where the sub-wavelength structure is fabricated on the surface of the silicon substrate and then coated with a passivation layer, the present invention can omit the problem of non-uniform coating of a passivation layer on the sub-wavelength structure by fabricating a sub-wavelength structure on a passivation layer. Meanwhile, in the case of fabricating a sub-wavelength structure on a passivation layer according to the present invention, the possibility of the semiconductor layer being damaged by reactive ion etching can be reduced, resulting in improved conversion efficiency of a photoelectric conversion device.

In the method for fabricating a sub-wavelength structure layer according to the present invention, preferably, the metal film is made of nickel, gold, silver or palladium.

In the method for fabricating a sub-wavelength structure layer according to the present invention, an etching process, preferably dry etching, may be performed to remove the partial area of the passivation layer, the n-GaN layer or the transparent conductive oxide layer.

In the method for fabricating a sub-wavelength structure layer according to the present invention, wet etching may be performed to remove the metal nano particles. For example, in the case of the metal nano particles being made of nickel or silver, an etchant of nitric acid may be used; in the case of the metal nano particles being made of gold, an etchant composed of potassium iodide and iodine may be used; in the case of the metal nano particles being made of palladium, an etchant composed of hydrochloride acid and nitric acid or hydrochloride acid and ammonia may be used.

In the method for fabricating a sub-wavelength structure layer according to the present invention, the density and diameter of the sub-wavelength structure are mainly associated with the density and size of the metal nano particles. Herein, preferably, the metal film has a thickness of from 5 nm to 20 nm, the metal nano particles have a diameter of from 70 nm to 300 nm, and the sub-wavelength structure has a height of from 150 nm to 160 nm.

Accordingly, the present invention further provides a sub-wavelength structure layer, which is a passivation layer, an n-GaN layer or a transparent conductive oxide layer of which a surface has a sub-wavelength structure, where the sub-wavelength structure has a height of from 150 nm to 160 nm, and the cross-sectional area of the sub-wavelength structure increases along the thickness direction of the passivation layer, the n-GaN layer or the transparent conductive oxide layer. Herein, the passivation layer with the sub-wavelength structure may have a reflectivity of 10% or less over a wavelength from 400 nm to 700 nm and a reflectivity of 1% or less over a wavelength from 582 nm to 680 nm. Thereby, the passivation layer with a sub-wavelength structure provided by the present invention exhibits improved antireflection effect, and thus can enhance the amount of light extraction when being applied in a photoelectric conversion device as an antireflective layer to obtain a photoelectric conversion device with high efficiency, such as a solar cell. In addition, the n-GaN layer with a sub-wavelength structure provided by the present invention can be applied in LEDs or the like to enhance light output of LEDs or the like. Moreover, the transparent conductive oxide layer with the sub-wavelength structure can be applied in a thin-film solar cell or the like to enhance light trapping and thus improve light absorption.

Accordingly, the present invention further provides a photoelectric conversion device, including: a photoelectric conversion element comprising a first semiconductor layer and a second semiconductor layer located over the first semiconductor layer, where the first semiconductor layer and the second semiconductor layer are different from each other in electrical properties; optionally a first substrate located below the first semiconductor layer; an electrode pair including a first electrode and a second electrode, where the first electrode is connected to the first semiconductor layer or the first substrate and the second electrode is connected to the second semiconductor layer; and a sub-wavelength structure made of a passivation material, an n-GaN material or a transparent conductive oxide, which is located over the second semiconductor layer or is formed by removing a partial area of the second semiconductor layer or the second electrode, where the sub-wavelength structure has a height from 150 nm to 160 nm and a cross-sectional area increasing along the thickness direction of the second semiconductor layer. Specifically, the passivation material may be silicon nitride or silicon oxide, and the transparent conductive oxide may be tin oxide, indium tin oxide, zinc oxide, aluminum-doped zinc oxide, gallium-doped zinc oxide or indium zinc oxide.

In the case of the sub-wavelength structure being made of the passivation material, the photoelectric conversion device according to the present invention may further include a passivation layer located over the second semiconductor layer, where sub-wavelength structure may be formed by removing a partial area of the passivation layer. Herein, the second electrode may have an open area to expose the second semiconductor layer and the passivation layer may be located on the second semiconductor layer in the open area. Accordingly, the second electrode of the present invention may be designed into any conventional configuration with an open area. For example, the second electrode may be interdigitated-shaped, strip-shaped, or net-shaped, and preferably is interdigitated-shaped. Alternatively, the second electrode may be a transparent electrode and covers the second semiconductor layer, and the passivation layer may be located on the second electrode.

In the case of the sub-wavelength structure being made of the passivation material and formed by removing a partial area of a passivation layer, the first semiconductor layer may be a p-type semiconductor layer, and the second semiconductor layer may be an n-type semiconductor layer; or the first semiconductor layer may be an n-type semiconductor layer, and the second semiconductor layer may be a p-type semiconductor layer. Herein, the dopant of the p-type semiconductor layer may be elements from the group III on the periodic table, and the dopant of the n-type semiconductor layer may be elements from the group V on the periodic table.

In the case of the sub-wavelength structure being made of the passivation material and formed by removing a partial area of a passivation layer, the material of the first electrode is unlimited, and may be any suitable electrode materials used in the art. Preferably, the material of the first electrode is a material with high work function, to form an ohmic contact. One example of the first electrode is an Al electrode.

In the case of the sub-wavelength structure being made of the passivation material and formed by removing a partial area of a passivation layer, the material of the second electrode is unlimited, and may be any suitable electrode materials used in the art. Preferably, the material of the second electrode is a material with low work function, to form an ohmic contact and derive effective charge carriers effectively so as to improve the photoelectric conversion efficiency effectively. One example of the second electrode is an Ag electrode.

In the case of the sub-wavelength structure being made of the n-GaN material, the sub-wavelength structure may be formed by removing the partial area of the second semiconductor layer. Herein, the photoelectric conversion element may further include an active layer located between the first semiconductor layer and the second semiconductor layer.

In the case of the sub-wavelength structure being made of the n-GaN material and formed by removing the partial area of the second semiconductor layer, the first semiconductor layer may be a p-GaN layer, and the second semiconductor may be an n-GaN layer.

In the case of the sub-wavelength structure being made of the transparent conductive oxide, the second electrode may be a first transparent conductive oxide layer, and the sub-wavelength structure may be formed by removing the partial area of the second electrode. Herein, the photoelectric conversion element may further include an intrinsic layer located between the first semiconductor layer and the second semiconductor layer.

In the case of the second electrode is a first transparent conductive oxide layer and the sub-wavelength structure is formed by removing a partial area of the second electrode, the photoelectric conversion device may further include a second substrate located on the second electrode, where the second substrate may be a glass substrate, polymer substrate, metal substrate or other suitable substrate.

In the case of the second electrode is a first transparent conductive oxide layer and the sub-wavelength structure is formed by removing a partial area of the second electrode, the first electrode may include a contact layer and a second transparent conductive oxide layer, and the second transparent conductive oxide layer is located between the contact layer and the first semiconductor layer. Herein, the second transparent conductive oxide layer may be made of tin oxide, indium tin oxide, zinc oxide, aluminum-doped zinc oxide, gallium-doped zinc oxide or indium zinc oxide, and the material of the first transparent conductive oxide layer may be different from or the same as that of the second transparent conductive oxide layer. Additionally, the contact layer may be a metal layer.

### BRIEF DESCRIPTION OF THE DRAWINGS

FIG. 1A shows a schematic view of a conventional solar cell;

FIG. 1B shows a schematic view of another conventional solar cell;

FIG. 1C shows a cross-sectional view of a conventional thin-film solar cell;

FIG. 1D shows a cross-sectional view of a conventional GaN-based LED;

FIGS. 2A to 2E show a process for fabricating a sub-wavelength structure layer on a silicon wafer according to the present invention;

FIG. 3 shows a diagram for comparing the reflectivity of the sample according to Example 1 with those according to Comparative Examples 1 to 3;

FIG. 4 shows a schematic view of a photoelectric conversion device according to Example 3 of the present invention;

FIG. 5 shows a schematic view of a photoelectric conversion device according to Example 4 of the present invention.

FIGS. 6A to 6F show a process for fabricating a photoelectric conversion device according to Example 5 of the present invention;

FIG. 7 shows a schematic view of a photoelectric conversion device according to Example 6 of the present invention;

FIGS. 8A to 8G show a process for fabricating a photoelectric conversion device according to Example 7 of the present invention;

FIG. 9 shows a schematic view of a photoelectric conversion device according to Example 8 of the present invention; and

FIG. 10 shows a schematic view of a photoelectric conversion device according to Example 9 of the present invention

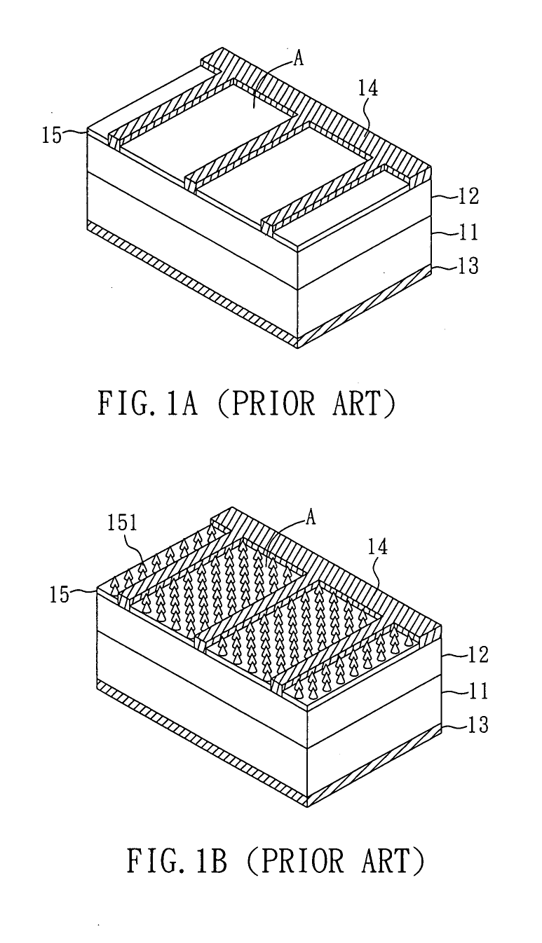

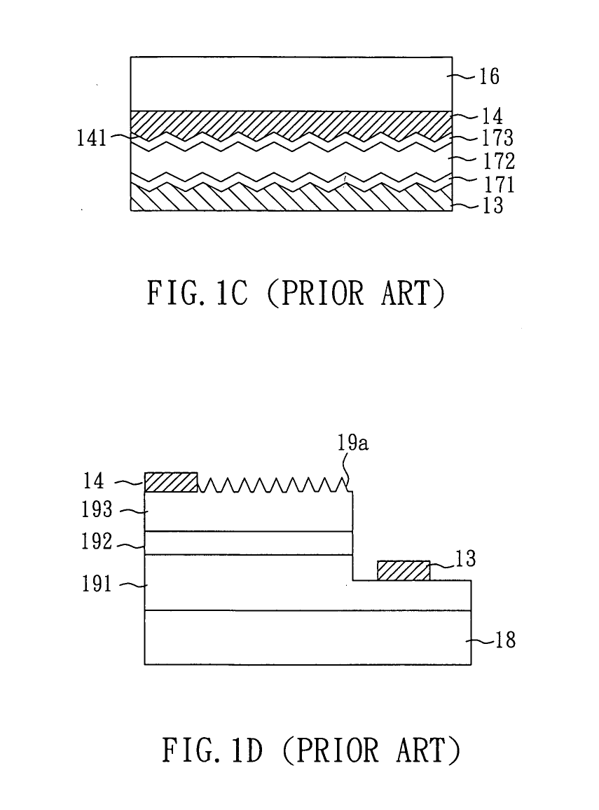

### DETAILED DESCRIPTION OF THE PREFERRED EMBODIMENT

Herein below, the present invention will be described in detail with reference to the Embodiments. The present invention may, however, be embodied in many different forms and should not be construed as being limited to the Embodiments set forth herein. Rather, these Embodiments are provided to fully convey the concept of the invention to those skilled in the art.

### Example 1

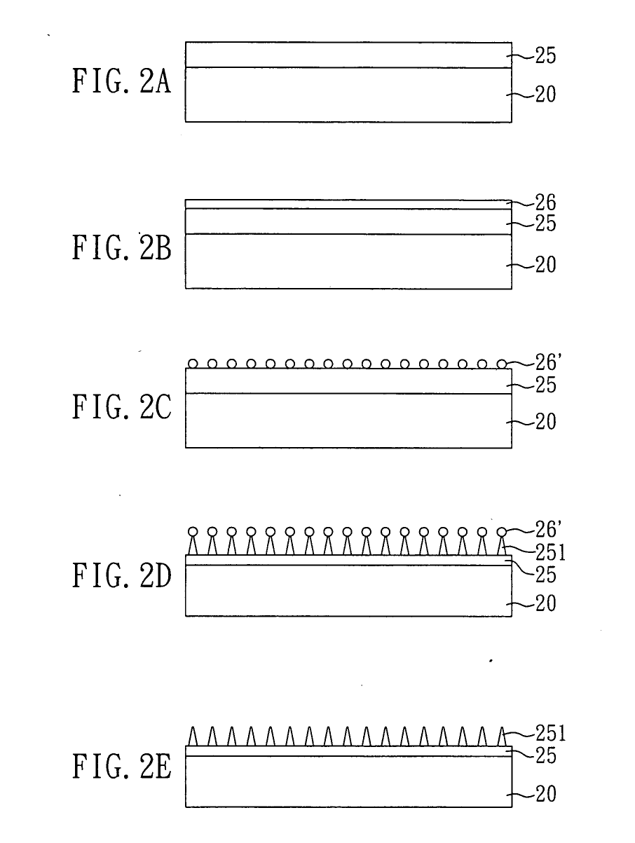

FIGS. 2A to 2E show a process for fabricating a sub-wavelength structure layer as an antireflective layer on a silicon wafer.

First, as shown in FIG. 2A, a (100) silicon wafer 20 was cleaned with diluted HF to remove the native oxide. Subsequently, a 200±5 nm thick passivation layer 25 was deposited on the silicon wafer 20 by plasma enhanced chemical vapor deposition (PECVD) technique. In the present example, the passivation layer 25 was a silicon nitride (Si₃N₄) layer.

Next, as shown in FIG. 2B, a metal film 26 with a thickness of 15±0.5 nm was evaporated on the surface of the passivation layer 25 using an E-beam evaporating system. In the present example, the metal film 26 was made of nickel.

As shown in FIG. 2C, the metal film was then rapid-thermally annealed under the gas mixture of H₂ and N₂ with a flow rate of 3 sccm at 850° C. for 60 seconds to form self-assembled metal nano particles 26′ (owing to surface tension), which served as a mask for the passivation layer 25. After the heat treatment on the metal film, the metal nano particles with the diameter ranging from about 70 nm to 130 nm were observed.

Subsequently, as shown in FIG. 2D, the passivation layer 25 was etched by inductively coupled plasma (ICP) for 120 seconds to form a sub-wavelength structure 251. In the present example, a CF₄/O₂ etching gas with and flow rate of 60 and 6 sccm for CF₄ and O₂ was used and the bias power was set as 200 watts.

Finally, as shown in FIG. 2E, the sample was dipped into pure nitric acid solution for 5 minutes to remove the residual metal nano particles, such that the passivation layer with a sub-wavelength structure being about 150 nm to 160 nm in height was fabricated on the silicon wafer 20.

### Example 2

The fabricating process was the same as that illustrated in the Example 1, except that the metal film was made of gold and the metal nano particles were removed using an etchant composed of potassium iodide and iodine. In the present example, the heat treatment was performed on the metal film at 850° C. for 60 seconds.

### Comparative Examples 1-3

An untreated blank silicon wafer was taken as a sample of Comparative Example 1. In Comparative Example 2, a single-layer antireflective layer of silicon nitride with a thickness of 69.1 nm was formed on a silicon wafer by coating. In Comparative Example 3, a 69.1 nm thick silicon nitride layer and a 56.0 thick magnesium fluoride layer were coated on a silicon wafer in sequence to fabricate a two-layer antireflective layer.

### Experimental Example

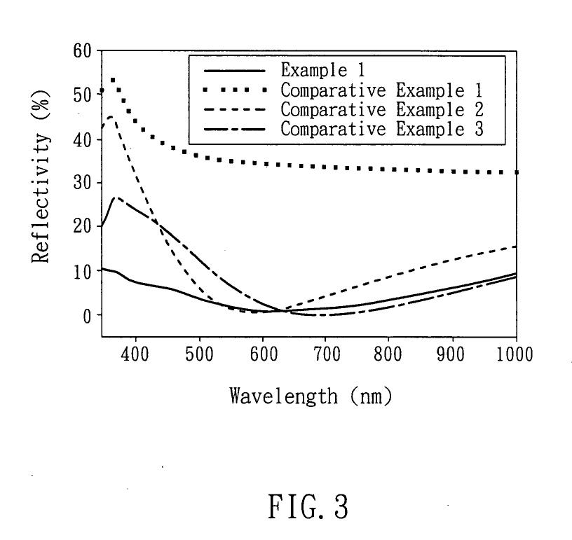

The sample of Example 1 was compared to those of Comparative Examples 1 to 3 in reflectivity, and the result is shown in FIG. 3. As shown in FIG. 3, the untreated blank silicon wafer (Comparative Example 1) exhibits high reflection >35% for visible and near infrared wavelengths; the single-layer antireflective layer of silicon nitride (Comparative Example 2) exhibits low reflection <20% for long wavelength 700 nm and high reflection >35% for shorter wavelength 400 nm; and the two-layer antireflective layer of silicon nitride/magnesium fluoride (Comparative Example 3) exhibits low reflection <10% for long wavelength 700 nm and high reflection >20% for shorter wavelength 400 nm, while the sub-wavelength structure of silicon nitride (Example 1) shows reflection <10% for wavelengths from 400 nm to 700 nm and reduced reflection <1% for wavelengths from 580 nm to 680 nm.

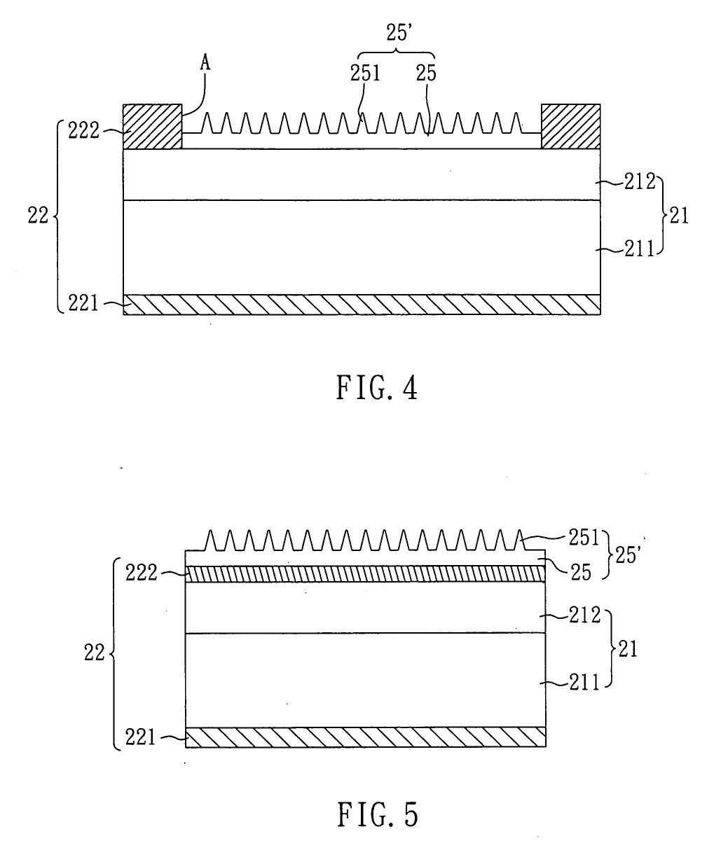

Thereby, it can be confirmed that the antireflective layer according to the present invention exhibits an excellent antireflection effect, and thus can enhance the amount of light extraction when being applied in a photoelectric conversion device, such that a photoelectric conversion device with high efficiency can be obtained. FIGS. 4 and 5 show schematic views of photoelectric conversion devices in which the antireflective layer according to the present invention is applied.

### Example 3

As shown in FIG. 4, the photoelectric conversion device (i.e. a solar cell) according to the present example includes: a photoelectric conversion element 21 including a first semiconductor layer 211 and a second semiconductor layer 212 located on the first semiconductor layer 211, where the first semiconductor layer 211 and the second semiconductor layer 212 are different from each other in electrical properties; an electrode pair 22 including a first electrode 221 and a second electrode 222, where the first electrode 221 is connected to the first semiconductor layer 211, the second electrode 222 is connected to the second semiconductor layer 212, and the second electrode 222 has an open area A to expose the second semiconductor layer 212; a passivation layer 25 located on the second semiconductor layer 212 in the open area A; and a sub-wavelength structure 251 made of a passivation material, which is formed by removing a partial area of the passivation layer 25. Accordingly, the photoelectric conversion device according to the present example uses a passivation layer 25 of which a surface has a sub-wavelength structure 251 as an antireflective layer 25′. Herein, the sub-wavelength structure 251 has a height from 150 nm to 160 nm and a cross-sectional area increasing along the thickness direction of the second semiconductor layer 212/the passivation layer 25. In detail, the sub-wavelength structure 251 is composed of plural pyramid-like elements on the surface of the passivation layer 25.

In the present example, the antireflective layer 25′ is made of silicon nitride, and the second electrode 222 is designed in an interdigitated form.

### Example 4

As shown in FIG. 5, the photoelectric conversion device (i.e. a solar cell) according to the present example is the same as that illustrated in Example 3, except that the second electrode 222 used in the present example is a transparent electrode and covers the second semiconductor layer 212, and the passivation layer 25 with the sub-wavelength structure 251 is located on the second electrode 222 as an antireflective layer 25′.

### Example 5

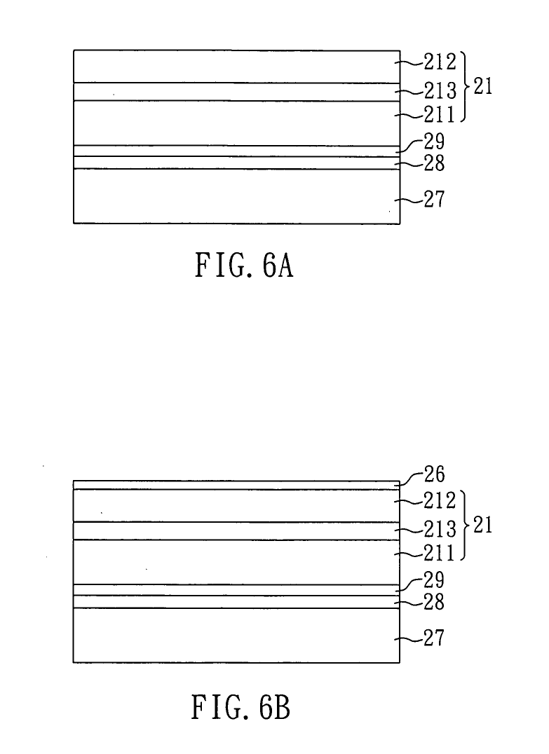

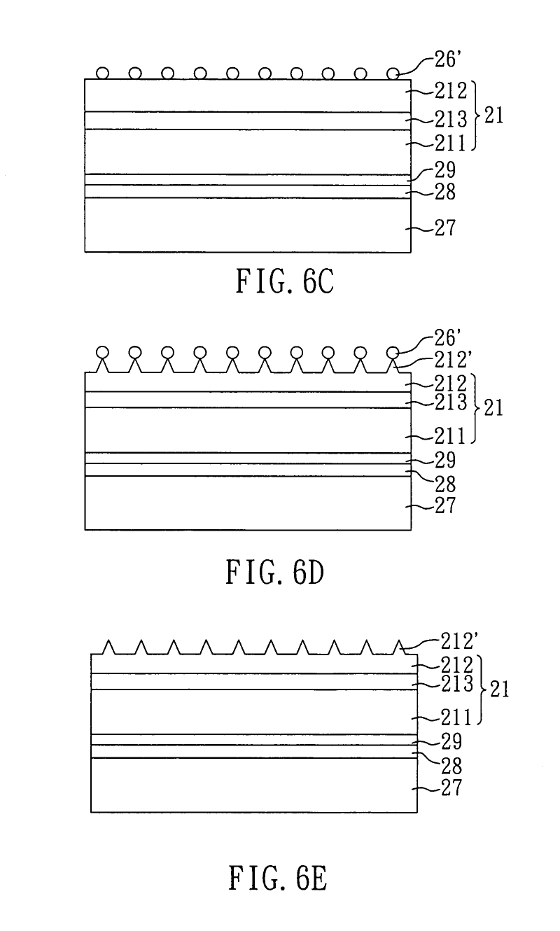

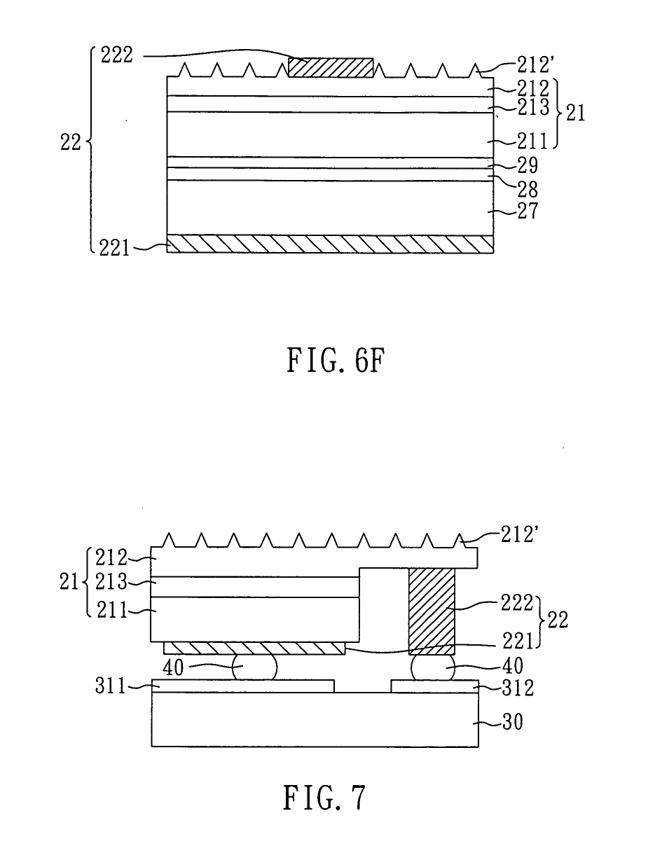

FIGS. 6A to 6F show a process for fabricating a photoelectric conversion device (i.e. a thin-GaN LED) according the present example.

First, as shown in FIG. 6A, a photoelectric conversion element 21, including a first semiconductor layer 211, a an active layer 213 located on the first semiconductor layer 211, and a second semiconductor layer 212 located on the active layer 213, was bonded to a first substrate 27 through an ohmic contact layer 29 and a bonding layer 28. In the present example, the first semiconductor layer 211 was a p-GaN layer, the second semiconductor layer 212 was an n-GaN layer, and the first substrate 27 was a conductive metal substrate.

Next, as shown in FIG. 6B, a metal film 26 with a thickness of 15±0.5 nm was evaporated on the surface of the second semiconductor layer 212 (i.e. an n-GaN layer) using an E-beam evaporating system. In the present example, the metal film 26 was made of silver.

As shown in FIG. 6C, the metal film was then rapid-thermally annealed under the gas mixture of H₂ and N₂ with a flow rate of 3 sccm at 850° C. for 60 seconds to form self-assembled metal nano particles 26′, which served as a mask for the second semiconductor layer 212.

Subsequently, as shown in FIG. 6D, the second semiconductor layer 212 was etched by inductively coupled plasma (ICP) for 40 seconds to form a sub-wavelength structure 212′. In the present example, a Cl₂/BCl₃ etching gas with and flow rate of 25 and 15 sccm for Cl₂/BCl₃ was used and the bias power was set as 200 watts.

Then, as shown in FIG. 6E, the residual metal nano particles were removed by pure nitric acid solution for 5 minutes.

Finally, as shown in FIG. 6F, a first electrode 221 and a second electrode 222 were formed and connected to the first substrate 27 and the second semiconductor layer 212, respectively.

Accordingly, as shown in FIG. 6F, the thin-GaN LED according to the present example includes: a photoelectric conversion element 21, including a first semiconductor layer 211, a second semiconductor layer 212, and an active layer 213 located between the first semiconductor layer 211 and the second semiconductor layer 212, where the first semiconductor layer 211 and the second semiconductor layer 212 are different from each other in electrical properties; a first substrate 27, located below the first semiconductor layer 211 and bonded to the first semiconductor layer 211 through the bonding layer 28 and the ohmic contact layer 29; an electrode pair 22 including a first electrode 221 and a second electrode 222, where the first electrode 221 is connected to the first substrate 27, and the second electrode 222 is connected to the second semiconductor layer 212; and a sub-wavelength structure 212′, formed by removing a partial area of the second semiconductor layer 212, and having a height from 150 nm to 160 nm and a cross-sectional area increasing along the thickness direction of the semiconductor layer 212. In detail, the sub-wavelength structure 212′ is composed of plural pyramid-like elements on the surface of the second semiconductor layer 212.

### Example 6

As shown in FIG. 7, the photoelectric conversion device (i.e. a thin-GaN flip-chip LED) according to the present example includes: a submount 30 having a first contact 311 and a second contact 312 on one surface thereof; a photoelectric conversion element 21 including a first semiconductor layer 211, a second semiconductor layer 212, and an active layer 213 located between the first semiconductor layer 211 and the second semiconductor layer 212, where the first semiconductor layer 211 and the second semiconductor layer 212 are different from each other in electrical properties; an electrode pair 22 including a first electrode 221 and a second electrode 222, where the first electrode 221 is connected to the first semiconductor layer 211 and bonded to the first contact 311 through a bump 40, and the second electrode 222 is connected to the second semiconductor layer 212 and bonded to the second contact 312 through a bump 40; and a sub-wavelength structure 212′, formed by removing a partial area of the second semiconductor layer 212, and having a height from 150 nm to 160 nm and a cross-sectional area increasing along the thickness direction of the semiconductor layer 212. In detail, the sub-wavelength structure 212′ is composed of plural pyramid-like elements on the surface of the second semiconductor layer 212.

In the present example, the first semiconductor layer 211 is a p-GaN layer, and the second semiconductor layer 212 is an n-GaN layer.

### Example 7

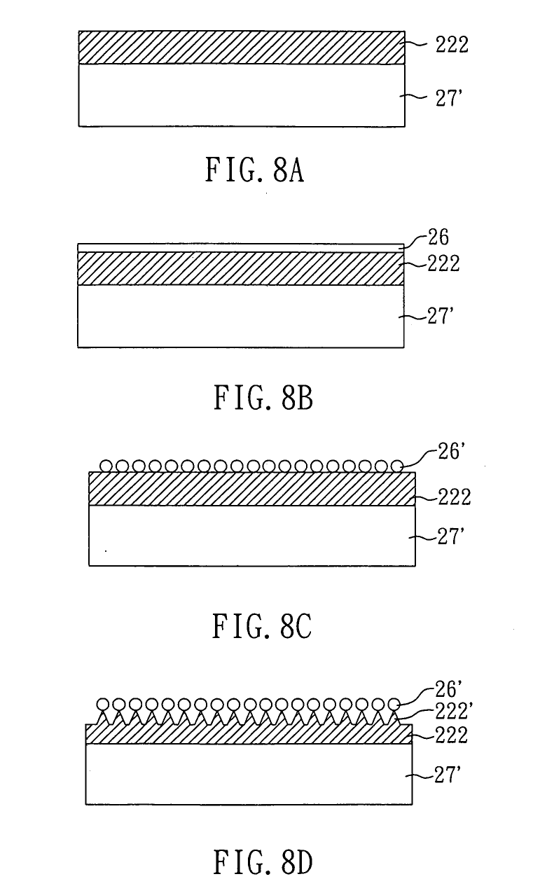

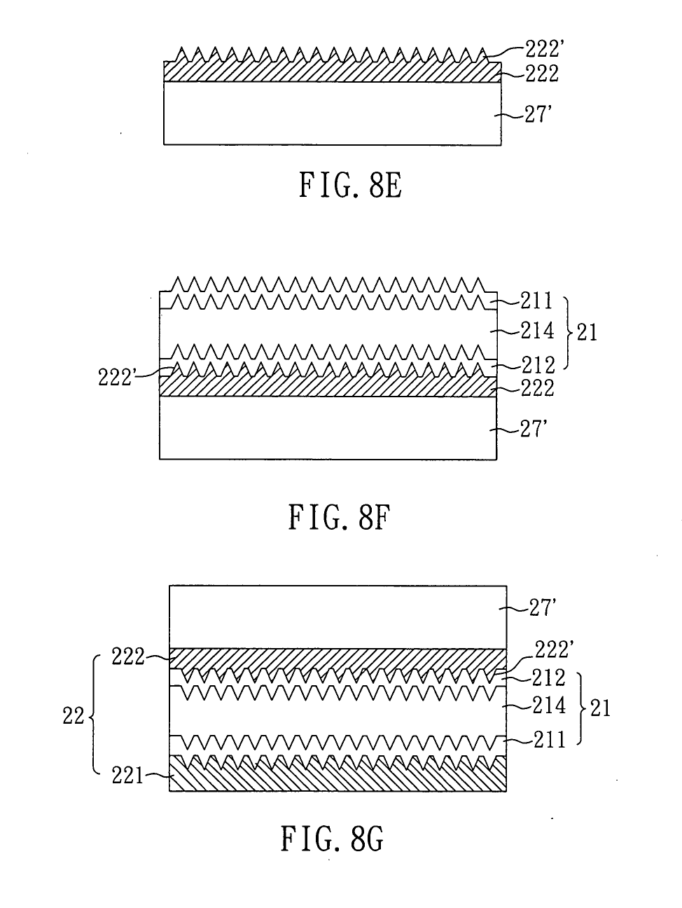

FIGS. 8A to 8G show a process for fabricating a photoelectric conversion device (i.e. a thin-film solar cell) according the present example.

First, as shown in FIG. 8A, a second substrate 27′ with a second electrode 222 thereon was provided. In the present example, the second substrate 27′ was a glass substrate and the second electrode 222 was a transparent conductive oxide layer made of indium tin oxide or aluminum-doped zinc oxide.

Next, as shown in FIG. 8B, a metal film 26 with a thickness of 15±0.5 nm was evaporated on the surface of the second electrode 222 using an E-beam evaporating system. In the present example, the metal film 26 was made of palladium.

As shown in FIG. 8C, the metal film was then rapid-thermally annealed under the gas mixture of H₂ and N₂ with a flow rate of 3 sccm at 850° C. for 60 seconds to form self-assembled metal nano particles 26′, which served as a mask for the second electrode 222.

Subsequently, as shown in FIG. 8D, the second electrode 222 was etched by inductively coupled plasma (ICP) for 120 seconds to form a sub-wavelength structure 222′. In the present example, a Cl₂ etching gas with flow rate of 20 sccm was used and the bias power was set as 200 watts.

Then, as shown in FIG. 8E, the residual metal nano particles were removed by an etchant composed of hydrochloride acid and nitric acid for 5 minutes.

As shown in FIG. 8F, a second semiconductor layer 212, an intrinsic layer 214 and a first semiconductor layer 211 were deposited over the second electrode 222 in sequence to form a photoelectric conversion element 21. Herein, the first semiconductor layer 211 was an n-type semiconductor layer, and the second semiconductor layer 212 was a p-type semiconductor layer.

Finally, as shown in FIG. 8G, a first electrode 221 was formed and connected to the first semiconductor layer 211. Herein, the first electrode 221 was a metal layer.

Accordingly, as shown in FIG. 8G, the thin-film solar cell according to the present example includes: a photoelectric conversion element 21, including a first semiconductor layer 211, a second semiconductor layer 212, and an intrinsic layer 214 located between the first semiconductor layer 211 and the second semiconductor layer 212, where the first semiconductor layer 211 and the second semiconductor layer 212 are different from each other in electrical properties; an electrode pair 22 including a first electrode 221 and a second electrode 222, where the first electrode 221 is connected to the first semiconductor layer 211, and the second electrode 222 is a transparent conductive oxide layer and connected to the second semiconductor layer 212; a second substrate 27′ located on the second electrode 222; and a sub-wavelength structure 222′, formed by removing a partial area of the second electrode 222, and having a height from 150 nm to 160 nm and a cross-sectional area increasing along the thickness direction of the semiconductor layer 212/the second electrode 222 (i.e. a transparent conductive oxide layer). In detail, the sub-wavelength structure 222′ is composed of plural pyramid-like elements on the surface of the second electrode 222 (i.e. a transparent conductive oxide layer).

### Example 8

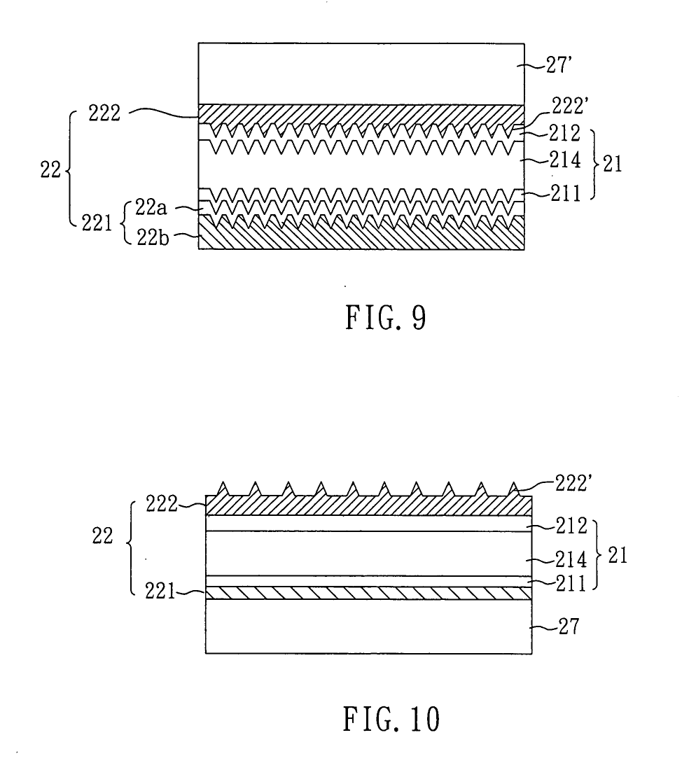

As shown in FIG. 9, the structure of the thin-film solar cell according to the present example is the same as that illustrated in Example 7, except that the first electrode 221 according to the present example has a two-layered structure and includes a second transparent conductive oxide layer 22a and a contact layer 22b, and the second transparent conductive oxide layer 22a is located between the contact layer 22b and the first semiconductor layer 211. Herein, the second electrode 222 is a first transparent conductive oxide layer made of indium tin oxide (ITO), the second transparent conductive oxide layer 22a is made of ITO, and the contact layer 22b is made of aluminum.

### Example 9

As shown in FIG. 10, the photoelectric conversion device (i.e. a thin-film solar cell) according to the present example includes: a photoelectric conversion element 21, including a first semiconductor layer 211, a second semiconductor layer 212, and an intrinsic layer 214 located between the first semiconductor layer 211 and the second semiconductor layer 212, where the first semiconductor layer 211 and the second semiconductor layer 212 are different from each other in electrical properties; an electrode pair 22 including a first electrode 221 and a second electrode 222, where the second electrode 222 is a transparent conductive oxide layer, the first electrode 221 is connected to the first semiconductor layer 211, and the second electrode 222 is connected to the second semiconductor layer 212; a first substrate 27 connected to the first electrode 221; and a sub-wavelength structure 222′, formed by removing a partial area of the second electrode 222, and having a height from 150 nm to 160 nm and a cross-sectional area increasing along the thickness direction of the semiconductor layer 212/the second electrode 222 (i.e. a transparent conductive oxide layer). In detail, the sub-wavelength structure 222′ is composed of plural pyramid-like elements on the surface of the second electrode 222 (i.e. a transparent conductive oxide layer).

In the present example, the first semiconductor layer 211 is an n-type semiconductor layer, the second semiconductor layer 212 is a p-type semiconductor layer, the first electrode 221 is a silver layer, the second electrode 222 is an aluminum-doped zinc oxide (AZO) layer, and the first substrate 27 is a plastic substrate.

Although the present invention has been explained in relation to its preferred embodiment, it is to be understood that many other possible modifications and variations can be made without departing from the scope of the invention as hereinafter claimed.

What is claimed is:

1. A method for fabricating a sub-wavelength structure layer, comprising:
forming a metal film on a passivation layer, an n-GaN layer or a transparent conductive oxide layer;
performing thermal treatment on the metal film to form self assembled metal nano particles;
using the metal nano particles as a mask to remove a partial area of the passivation layer, the n-GaN layer or the transparent conductive oxide layer to form a sub-wavelength structure, wherein the cross-sectional area of the sub-wavelength structure increases along the thickness direction of the passivation layer, the n-GaN layer or transparent conductive oxide layer; and removing the metal nano particles.

2. The method as claimed in claim 1, wherein the passivation layer is made of silicon nitride or silicon oxide, and the transparent conductive oxide layer is made of tin oxide, indium tin oxide, zinc oxide, aluminum-doped zinc oxide, gallium-doped zinc oxide or indium zinc oxide.

3. The method as claimed in claim 1, wherein the metal film is made of nickel, gold, silver or palladium.

4. The method as claimed in claim 1, wherein an etching process is performed to remove the partial area of the passivation layer, the n-GaN layer or the transparent conductive oxide layer.

5. The method as claimed in claim 4, wherein the etching process is dry etching.

6. The method as claimed in claim 1, wherein wet etching is performed to remove the metal nano particles.

7. The method as claimed in claim 1, wherein the metal film has a thickness of from 5 nm to 20 nm.

8. The method as claimed in claim 1, wherein the metal nano particles have a diameter of from 70 nm to 300 nm.

9. The method as claimed in claim 1, wherein the sub-wavelength structure has a height of from 150 nm to 160 nm.

10. The method as claimed in claim 1, wherein the passivation layer with the sub-wavelength structure has a reflectivity of 10% or less over a wavelength from 400 nm to 700 nm and a reflectivity of 1% or less over a wavelength from 582 nm to 680 nm.

11. A sub-wavelength structure layer, which is a passivation layer, an n-GaN layer or a transparent conductive oxide layer of which a surface has a sub-wavelength structure, wherein the sub-wavelength structure has a height of from 150 nm to 160 nm, and the cross-sectional area of the sub-wavelength structure increases along the thickness direction of the passivation layer, the n-GaN layer or the transparent conductive oxide layer.

12. The sub-wavelength structure layer as claimed in claim 11, wherein the passivation layer is made of silicon nitride or silicon oxide, and the transparent conductive oxide layer is made of tin oxide, indium tin oxide, zinc oxide, aluminum-doped zinc oxide, gallium-doped zinc oxide or indium zinc oxide.

13. The sub-wavelength structure layer as claimed in claim 11, wherein the passivation layer with the sub-wavelength structure has a reflectivity of 10% or less over a wavelength from 400 nm to 700 nm and a reflectivity of 1% or less over a wavelength from 582 nm to 680 nm.

14. A photoelectric conversion device, comprising:
a photoelectric conversion element comprising a first semiconductor layer and a second semiconductor layer located over the first semiconductor layer, wherein the first semiconductor layer and the second semiconductor layer are different from each other in electrical properties;
optionally a first substrate located below the first semiconductor layer;
an electrode pair comprising a first electrode and a second electrode, wherein the first electrode is connected to the first semiconductor layer or the first substrate and the second electrode is connected to the second semiconductor layer; and
a sub-wavelength structure made of a passivation material, an n-GaN material or a transparent conductive oxide, which is located over the second semiconductor layer or is formed by removing a partial area of the second semiconductor layer or the second electrode, wherein the sub-wavelength structure has a height from 150 nm to 160 nm and a cross-sectional area increasing along the thickness direction of the second semiconductor layer.

15. The photoelectric conversion device as claimed in claim 14, wherein the passivation material is silicon nitride or silicon oxide, and the transparent conductive oxide is tin oxide, indium tin oxide, zinc oxide, aluminum-doped zinc oxide, gallium-doped zinc oxide or indium zinc oxide.

16. The photoelectric conversion device as claimed in claim 14, further comprising a passivation layer located over the second semiconductor layer, wherein the sub-wavelength structure is made of the passivation material and formed by removing a partial area of the passivation layer.

17. The photoelectric conversion device as claimed in claim 16, wherein the passivation layer with the sub-wavelength structure on the surface thereof has a reflectivity of 10% or less over a wavelength from 400 nm to 700 nm and a reflectivity of 1% or less over a wavelength from 582 nm to 680 nm.

18. The photoelectric conversion device as claimed in claim 16, wherein the second electrode has an open area to expose the second semiconductor layer and the passivation layer is located on the second semiconductor layer in the open area.

19. The photoelectric conversion device as claimed in claim 16, wherein the second electrode is a transparent electrode and covers the second semiconductor layer, and the passivation layer is located on the second electrode.

20. The photoelectric conversion device as claimed in claim 14, wherein the sub-wavelength structure is made of the n-GaN material and formed by removing the partial area of the second semiconductor layer.

21. The photoelectric conversion device as claimed in claim 20, wherein the photoelectric conversion element further comprises an active layer located between the first semiconductor layer and the second semiconductor layer.

22. The photoelectric conversion device as claimed in claim 14, wherein the second electrode is a first transparent conductive oxide layer, and the sub-wavelength structure is formed by removing the partial area of the second electrode.

23. The photoelectric conversion device as claimed in claim 22, further comprising a second substrate located on the second electrode.

24. The photoelectric conversion device as claimed in claim 22, wherein the photoelectric conversion element further comprises an intrinsic layer located between the first semiconductor layer and the second semiconductor layer.

25. The photoelectric conversion device as claimed in claim 22, wherein the first electrode comprises a contact layer and a second transparent conductive oxide layer, and the second transparent conductive oxide layer is located between the contact layer and the first semiconductor layer.
